(19) United States
(12) Patent Application Publication
(10) Pub. No.: US 2016/0307704 A1
(43) Pub. Date: Oct. 20, 2016

(54) PHOTOVOLTAIC ARCHITECTURES INCORPORATING ORGANIC-INORGANIC HYBRID PEROVSKITE ABSORBER

(71) Applicant: UNIVERSITY OF WASHINGTON though its Center for Commericalization, Seattle, WA (US)

(72) Inventors: Hugh Hillhouse, Seattle, WA (US); Ian Braly, Seattle, WA (US)

(73) Assignee: University of Washington through its Center for Commercialization, Seattle, WA (US)

(21) Appl. No.: 15/101,787

(22) PCT Filed: Dec. 3, 2014
(86) PCT No.: PCT/US14/68376

§ 371 Date: Jun. 3, 2016

Related U.S. Application Data
(60) Provisional application No. 61/911,194, filed on Dec. 3, 2013.

(51) Int. Cl. H01G 9/20; H01L 51/44; H01L 51/00; H01L 27/30; H01L 51/42

(52) U.S. Cl. CPC H01G 9/2018; H01L 27/302; H01L 51/4213; H01L 51/0097; H01L 51/442; H01L 51/448; H01L 51/0046; H01L 51/0047; H01L 51/0077; H01L 51/006; H01L 51/0056; H01L 51/0035; H01L 51/0037

(57) ABSTRACT

Disclosed herein are back-contact electrode photovoltaic devices that incorporate hybrid perovskite absorber materials and utilize their properties in order to create an entirely new photovoltaic device architecture. The provided devices include a number of architectures, including single-absorber devices and tandem devices, all of which incorporate the BC configuration. This new class of devices yields not only high performance photovoltaic devices but also promises to reduce manufacturing cost and complexity.

### CROSS-REFERENCE TO RELATED APPLICATION

This application claims the benefit of U.S. Provisional Patent Application No. 61/911,194, filed Dec. 3, 2013, the disclosure of which is hereby incorporated by reference in its entirety.

### BACKGROUND

Hybrid perovskites (HPs) are an exciting new class of PV materials that have high charge carrier mobilities, long carrier lifetimes, tunable bandgaps, already exhibit PV efficiencies over 15%, and can be solution processed under 150° C. Generally, hybrid perovskites are semiconductor compounds with the formula ABX₃ (A=monovalent organic cation; B=divalent metal cation such as Pb, Sn, etc.; X=Cl⁻, Br⁻, I⁻). A continuous 3D inorganic network is formed via corner-sharing BX₆ octahedra. Organic cations occupy the cuboctahedral voids enclosed by eight adjacent BX₆ octahedra, balancing the charge of the inorganic network. The relationship between ionic radii and structural stability is governed by the tolerance factor: t=(r_{A}+r_{B})/[2^{1/2}(r_{B}+r_{X})], where r_{A}, r_{B} and r_{X} are the ionic radii for A, B and X ions, respectively. When t is between 0.76 and 1.03, a stable 3D perovskite structure can be formed.

The bandgaps of the 3D HPs are direct, and the absorption coefficients are very high. The material properties, particularly the bandgap, can be tuned via the choice of metal, halogen, and organic cation constituents. The optical dielectric value (which is the one relevant for photogenerated charge carrier separation) is 6.5 for CH₃NH₃PbI₃. The exciton binding energy has been measured to be 45 meV using temperature dependent absorption spectra, suggesting a Wannier-Mott exciton. As a result, HP device physics is expected to be more like that of inorganic semiconductors with free carriers as opposed to organic optoelectronic devices where electrons and holes are strongly bound as Frenkel excitons. However, unlike most inorganic semiconductors, HPs, particularly methylammonium lead iodide, appear to have very few point defects that facilitate non-radiative recombination. Both of these material properties endow HPs with long diffusion lengths (100-1000 nm) and long carrier lifetimes (>100 ns). In addition, HPs can be solution processed at low temperature which may enable low-cost processing options and integration into or onto existing devices. Hybrid perovskites are the most exciting new photovoltaic materials discovered in the past 30 years, and they have the possibility to yield high efficiency devices at low-cost from Earth abundant elements.

Hybrid perovskite based photovoltaic devices evolved from attempts to use HPs to replace dyes in sensitized mesostructured TiO₂ solar cells. One device archictecture that has achieved 15% PCE consists of the following layers: (1) FTO, (2) 20 nm thick compact TiO₂ layer, (3) 1 μm thick mesoporous TiO₂ layer infused with solution deposited hybrid perovskite (methyl ammonium lead iodide), (5) hole-transporting layer of Spiro-OMeTAD, and (6) gold or silver back contact. However, the present champion HP solar cell (based on published reports) reaches 15.7% PCE and is a planar device (no mesoporous TiO₂) with the hybrid perovskite deposited by vapor depositon. Additionally, all high PCE HP absorber layers are sandwiched by an electron-transport material (ETM; also referred to herein as an electron-selective layer, “ESL”) (a compact TiO₂ layer) and an electron-transport material (HTM; also referred to herein as a hole-selective layer, “HSL”) (a heavily lithium TFSI doped and oxidized spiro-OMeTAD layer).

The ability to fabricate devices with bandgaps ranging from 1.57 to 2.2 eV was established through the incorperation of bromide into the pure iodide HP, and device performances exceding 10% were demonstrated for absorbers with band gaps as high as 1.66 eV.

Despite their promise, further progress is required in order to capitalize on the promise of HP absorbers in photovoltaic devices.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, a photovoltaic (PV) device is provided. In one embodiment, the PV device includes:

an organic-inorganic hybrid perovskite (HP) layer comprising a top major surface and a bottom major surface; and

a hole-collecting electrode and an electron-collecting electrode, both disposed adjacent to the bottom major surface.

In another aspect, a tandem photovoltaic device is provided. In one embodiment, the tandem PV device includes:

(1) a first photovoltaic device portion, comprising
(i) an organic-inorganic hybrid perovskite (HP) layer comprising a top major surface and a bottom major surface;
(ii) an electron-collecting electrode disposed adjacent to the bottom major surface;
(iii) an electron-selective layer forming an interface between the electron-collecting electrode and the HP; and
(iv) a hole-selective layer in contact with the bottom major surface of the HP;

(2) a second photovoltaic device portion, comprising
(i) a photovoltaic layer, having a lower energy bandgap than the HP, and having a top major surface and a bottom major surface;
(ii) a transparent conductive layer disposed adjacent to the top major surface; and
(iii) a hole-collecting electrode disposed adjacent to the top major surface; and

(3) a recombination layer forming an interface between the hole-selective layer of the first photovoltaic device portion and the transparent conductive layer of the second photovoltaic device portion; wherein the recombination layer allows holes from the first photovoltaic device portion to combine with electrons from the second photovoltaic device portion.

In another aspect, a photovoltaic (PV) device is provided that includes:

an organic-inorganic hybrid perovskite (HP) layer comprising a top major surface and a bottom major surface; and

an electron-collecting electrode disposed adjacent to the bottom major surface; and

a nanofibers hole-collecting electrode disposed adjacent to the top major surface.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 schematically depicts a conventional top-contact tandem solar cell.

FIGS. 2A and 2B schematically depict a representative photovoltaic device in accordance with the disclosed embodiments, wherein FIG. 2A is a cross-sectional view and FIG. 2B is a plan view.

FIGS. 3A and 3B schematically depict a representative photovoltaic device in accordance with the disclosed embodiments, wherein FIG. 3A is a cross-sectional view and FIG. 3B is a plan view.

FIG. 4 schematically depicts a representative tandem photovoltaic device in accordance with the disclosed embodiments.

FIGS. 5A and 5B graphically illustrate modeled single junction photovoltaic devices in accordance with the disclosed embodiments.

FIG. 6 graphically illustrates a modeled tandem HP/CIGSe photovoltaic device in accordance with the disclosed embodiments.

FIG. 7A is a micrograph of metal nanofibers created by electrospinning; the reference bar is one micron.

FIG. 7B is a cross-sectional diagram of nanofibers comprising a metal electron collector (EC) core with an electron transport material (ETM) shell.

FIG. 7C is a top-view schematic diagram of an embodiment of EC/ETM nanofibers forming a photovoltaic device layer in accordance with the disclosed embodiments.

FIG. 8A illustrates a two-terminal tandem PV device incorporating a top-contact nanofibers-based electron-collector electrode embedded in a HP absorber layer in accordance with the disclosed embodiments.

FIG. 8B illustrates a two-terminal tandem PV device incorporating a back-contact nanofibers-based electron-collector electrode embedded in a HP absorber layer in accordance with the disclosed embodiments.

### DETAILED DESCRIPTION

Disclosed herein are back-contact (BC) electrode photovoltaic devices that incorporate hybrid perovskite (HP) absorber materials and utilize their properties in order to create an entirely new photovoltaic device architecture. The devices include a number of architectures, including single-absorber devices and tandem devices, all of which incorporate the BC configuration. This new class of devices yields not only high performance photovoltaic devices but also promises to reduce manufacturing cost and complexity.

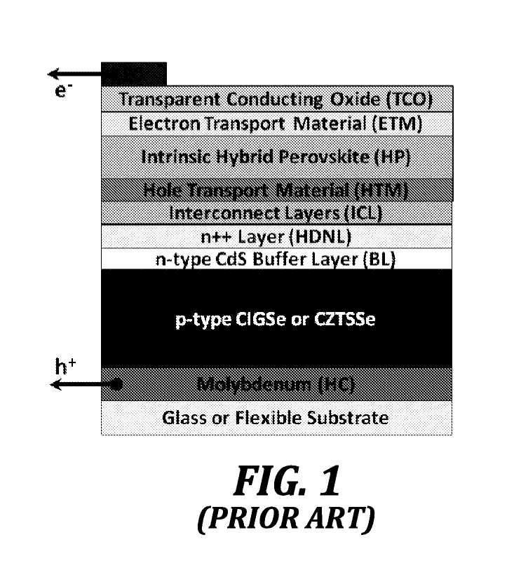

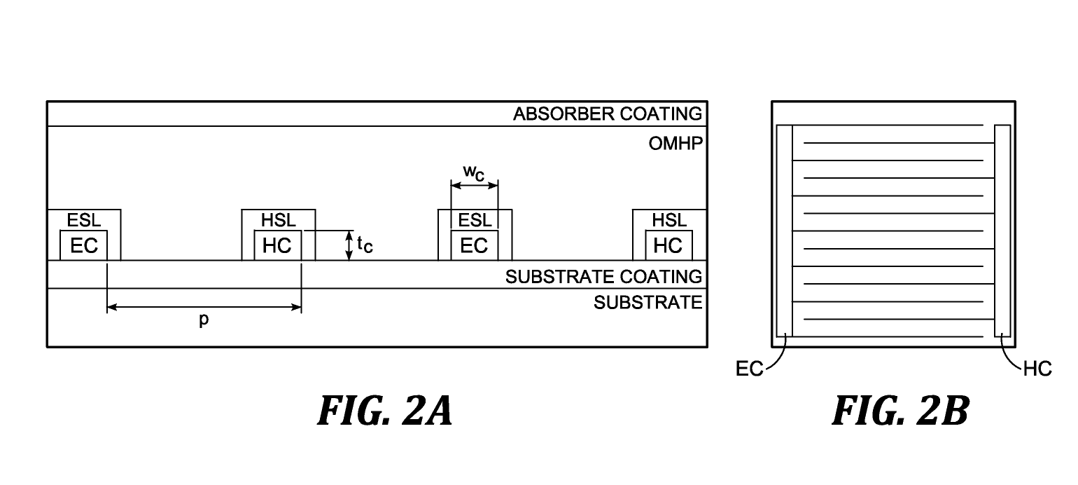

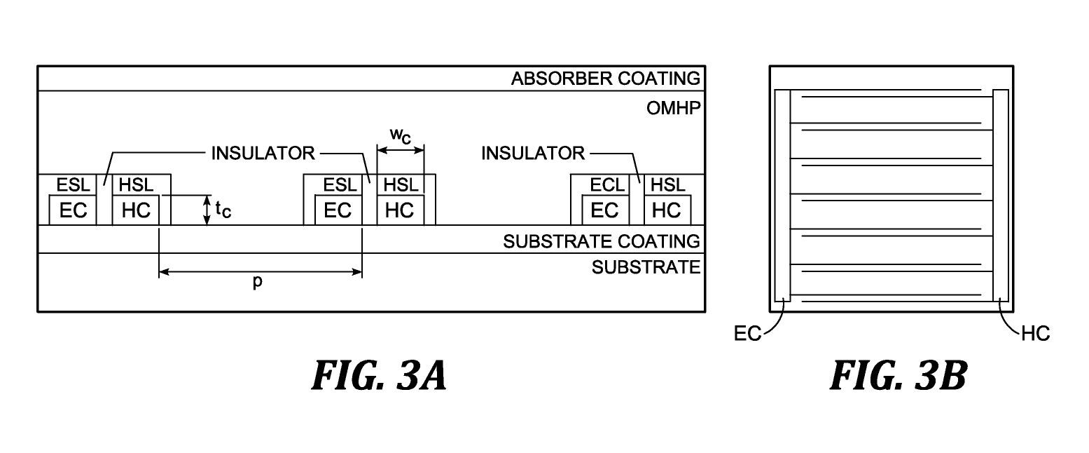

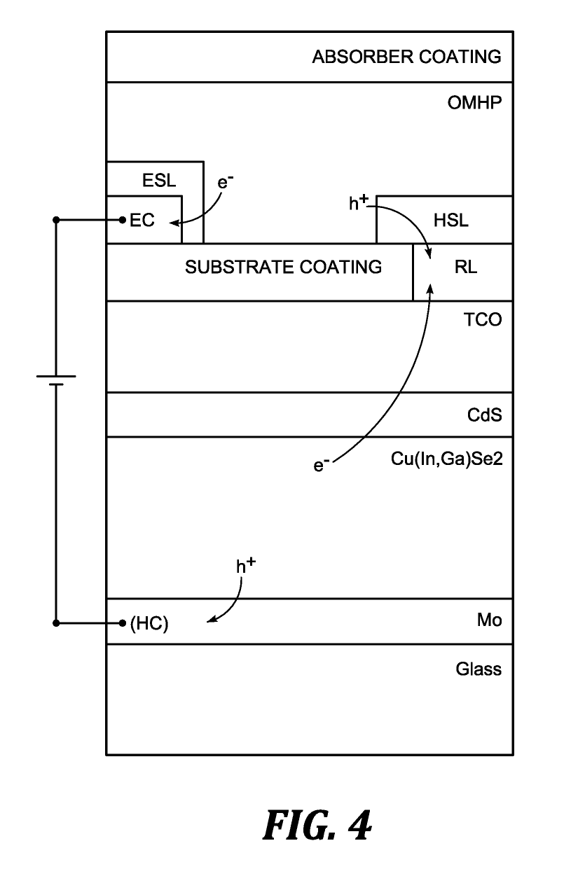

The disclosed devices provide several benefits, which are facilitated by the recognition that the long diffusion lengths and passive interfaces in HP absorbers allows for the movement of the traditional top electrode (electron-collecting contact, EC, of FIG. 1) a photovoltaic device to the back side of the device wherein it joins the traditional back contact (hole-collecting contact, HC) to form a closely arranged (e.g., interdigitated or overlapping) back-contact electrode configuration. The BC architecture can be implemented in single junction devices (e.g., FIGS. 2 and 3) and tandem devices (e.g., FIG. 4).

The BC configuration (1) avoids current losses due to shadowing that occur due to the a metal EC on the top surface; (2) avoids current losses (at λ<400 nm) due to absorption in the transparent conducting oxide layer, which is needed if the EC is on the top; (3) relaxes the constraint on band alignment imposed by a transparent conductive oxide (TCO) because it can now be set by the work function of the metal electron-collecting electrode (EC); (4) avoids current losses in a tandem bottom cell (for 400<λ<550 nm) that are usually suffered due to absorption in the bottom cell buffer layer (these photons are now captured by the top cell); and (5) relaxes NIR transmission constraints on the hole-transport material (HTM), which otherwise would need to be transparent out to about 1300 nm.

In one aspect, a photovoltaic (PV) device is provided. In one embodiment, the PV device includes:

an organic-inorganic hybrid perovskite (HP) layer comprising a top major surface and a bottom major surface; and

a hole-collecting electrode and an electron-collecting electrode, both disposed adjacent to the bottom major surface.

Basic HP PV devices have previously been developed. However, these PV devices all incorporate the HP into a standard PV device architecture (e.g., with a transparent conductive oxide top electrode and an opaque back electrode. In the aspects and embodiments disclosed herein, the unique properties of HPs are utilized in order to form a new type of PV device architecture that incorporates closely spaced electrodes disposed adjacent to the bottom side of the HP absorber layer. This architecture is not possible with traditional (non-HP) absorbers due to minimal charge diffusion lengths.

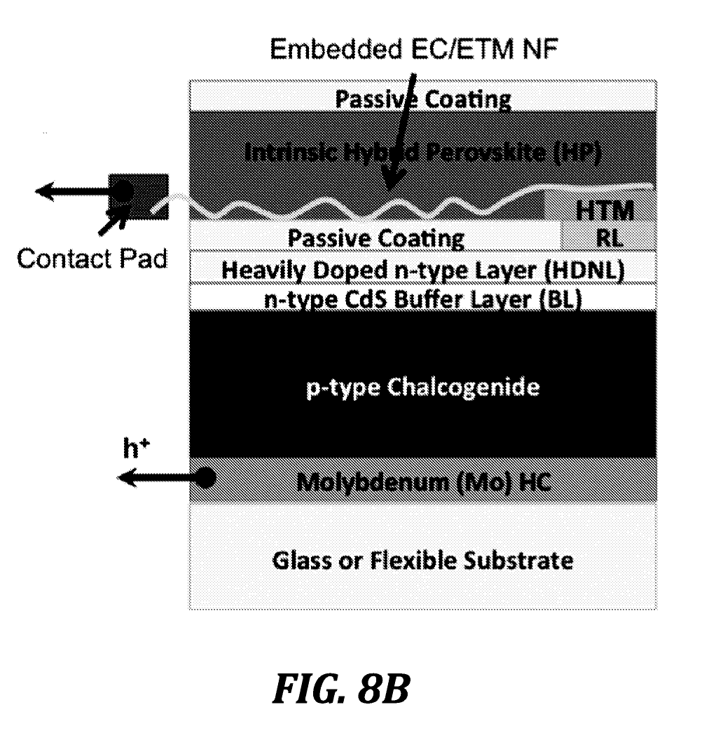

By being “disposed adjacent a bottom major surface” of the HP, the hole-collecting (HC) and electron-collecting (EC) electrodes are both positioned either external to but in contact with the bottom surface of the HP, or they are embedded within the HP in the lower half of the thickness of the HP layer. The external electrode configuration is illustrated in several figures, including FIGS. 2A, 3A, and 4. The embedded configuration is illustrated in FIG. 8B. As used herein, the term “embedded” indicates that the entire thickness of the electrode is enclosed within the HP. For practical reasons at least a contact portion of the embedded electrode must be outside of the HP.

Organic-Inorganic Hybrid Perovskite (HP)

The HP material can be any HP known to those of skill in the art presently or developed in the future. In one embodiment, the MP has the pervoskite structure A¹⁺B²⁺X¹⁻₃, wherein A is a monovalent organic cation; B is a divalent metal cation; and X is Cl⁻, Br⁻, or I⁻. In one embodiment, A is a primary alkyl-amine such as methylamine, ethyl amine, or 1-butylamine. In one embodiment, A is a secondary alkyl-amine such as 2-butylamine, or 2-propylamine. In one embodiment, B is a group IV element such as Ge, Sn, or Pb. In one embodiment, B is a non-group IV divalent cation such as Zn, Cu, or Ni.

In one embodiment, B has is partially substituted with one or more other divalent cations. For example: 50% Pb on B and 50% Sn on B; 50% Pb on B, 40% Sn on B, and 10% Zn on B.

In one embodiment, B alternates with +1 and +3 cations. For example: 50% Cu+ on B and 50% In+3 on B. The +1 cation is any of Li+, K+, Na+, Rb+, Cu+1, or Ag+1. The +3 cation is any of Al+3, In+3, Sb+3, or In+4.

In one embodiment, X is a halogen such as F, Cl, Br, or I. In one embodiment, X is partially substituted with mixed halogens. For example: 66.7% I and 33.3% Br.

In one embodiment, X is a non-halogen monovalent anion such as CN—, or N03—.

Electrodes

The electrodes can be made from any conductive material known to those of skill in the art.

In one embodiment, the electron-collecting electrode is a material selected from the group consisting of a metal, a metal alloy, a metal oxide, a doped metal oxide, an organic electron-conducting polymer, an organic electron-conducting small molecule, and combinations thereof. In one embodiment, the electron-collecting electrode is a metal or alloy selected from the group consisting of Al, Ca, Zn, Ag, Ni/Al, Cu, and alloys thereof. In one embodiment, the electron-collecting electrode is a doped or undoped metal oxide selected from the group consisting of ZnO, In₂O₃, SnO₂, F:Sn O₂, and F:In₂O₃. In one embodiment, the electron-collecting electrode is an electron conducting polymer or small molecule selected from the group consisting of fulleropyrrolidinium, PC₆₁BM, and graphene oxide-doped P3HT.

In one embodiment, the hole-collecting electrode is a material selected from the group consisting of a metal, a metal alloy, a metal oxide, a doped metal oxide, an organic hole-conducting polymer, an organic hole-conducting small molecule, and combinations thereof. In one embodiment, the hole-collecting electrode is a metal or alloy selected from the group consisting of Ag, Ni, Au, Cu, Mo, Ni/Al, Cu/Zn, and alloys thereof. In one embodiment, the hole-collecting electrode is a doped or undoped metal oxide selected from the group consisting of ITO, FTO, and ZnO. In one embodiment, the hole-collecting electrode is an electron conducting polymer or small molecule selected from the group consisting of tetraazabenzodifluoranthene, crosslinked thiophene-naphthalenediimide copolymer, and perylene diimide.

Charge-Selective Layers

In certain embodiments, charge-selective materials are incorporated in the device in order to selectively allow holes or electrons to pass to their respective electrodes while blocking the opposite charge from passing.

In one embodiment, the PV device further includes a hole-selective layer (HSL) forming an interface between the hole-collecting electrode and the HP. In one embodiment, the hole-selective layer is a material selected from the group consisting of small molecule organic hole-selective materials, polymer organic hole-selective materials, and combinations thereof. In one embodiment, the hole-selective layer is an organic compound selected from the group consisting of SpiroMeTAD, Triphenylamine, 1,3-Bis(N-carbazolyl)benzene, and N,N′-bis(tolyl)-N,N′ diphenyl-1, 1,′biphenyl-4,4′-diamine. In one embodiment, the hole-selective layer is a polymer selected from the group consisting of P3HT, Polytriarylamine, and poly(styrensulfonate) grafted onto polyaniline.

In one embodiment, the PV device further includes an electron-selective layer (ESL) forming an interface between the electron-collecting electrode and the HP. In one embodiment, the electron-selective layer is a material selected from the group consisting of organic electron-conductive materials, a metal, a metal oxide, and combinations thereof. In one embodiment, the electron-selective layer is a material selected from the group consisting of graphene, C₆₀, C₇₀, PCBM, polystyrenesulfonate, and carbon nanotubes. In one embodiment, the electron-selective layer is a metal or metal oxide selected from the group consisting of ZnO, In₂O₃, SnO₂, F:Sn O₂, and F:In₂O₃.

In one embodiment, the PV device further includes a hole-selective layer forming an interface between the hole-collecting electrode and the HP; and an electron-selective layer forming an interface between the electron-collecting electrode and the HP.

Device Configurations

The PV devices can be configured in any manner compatible with the disclosed embodiments. Traditional thin film and semiconductor techniques can be used to fabricate certain embodiments of the devices disclosed herein.

Exemplary device configurations are illustrated in FIGS. 2A and 2B, which disclose single junction devices with interdigitated electrodes. Accordingly, in one embodiment, the hole-collecting electrode and the electron-collecting electrode are interdigitated. As used herein, the term “interdigitated” refers to the arrangement of two or more electrodes that have portions that extend in close proximity to each other. For example, in FIG. 2B, the EC and HC electrodes extend in “fingers” towards each other from buses on opposite sides of the device. This configuration is referred to herein as a comb-like interdigitated electrode structure. Therefore, in a further embodiment, the hole-collecting electrode and the electron-collecting electrode are interdigitated in a comb-like configuration.

Referring again to FIG. 2B, a plan view of the electrode configuration of a representative PV device, the interdigitated fingers of the HC and EC are evenly distributed across the surface, equidistant from each other. In an alternative configuration, the EC and HC are closely grouped, as illustrated in FIGS. 3A and 3B, which provides the same area coverage as the embodiment of FIGS. 2A and 2B, but leaves larger open spaces between the electrode pairs. As a trade-off for the tight grouping of electrodes in the embodiment of FIGS. 3A and 3B, an additional insulating layer is inserted between the HC and EC, whereas the distance between the HC and EC in FIGS. 2A and 2B is sufficient that no short occurs, even with no insulating layer.

Referring to FIGS. 2A-3B, representative device dimensions include the pitch (p), collector electrode thickness (t_{c}), and collector electrode width (w_{c}).

In one embodiment, the hole-collecting electrode has a width of 0.01 micron to 50 microns. In one embodiment, the electron-collecting electrode has a width of 0.01 micron to 50 microns. In one embodiment, the hole-collecting electrode has a thickness of 0.01 micron to 50 microns. In one embodiment, the electron-collecting electrode has a thickness of 0.01 micron to 50 microns. In one embodiment, the pitch is 1 micron to 100 microns.

In one embodiment, the hole-collecting electrode and the electron-collecting electrode combine to cover 15% or less of the bottom major surface.

In one embodiment the PV device further includes a substrate disposed adjacent the bottom major surface. As illustrated in FIGS. 2A and 3A, the electrodes and/or HP are disposed on a substrate or substrate coating in certain embodiments.

In one embodiment, the HP is disposed directly on the substrate. In a further embodiment, the substrate is a single crystal selected to yield epitaxial growth of the HP.

In one embodiments, the substrate is selected from the group consisting of glass, metal foil, polymer, amorphous carbon, and graphite.

In further embodiments, the substrate is coated, for example to provide a compatible layer between mismatched HP and substrate layers. In one embodiment, the coating is transparent from the HP bandgap to 1300 nm. In one embodiment, the coating is a polymer selected from the group consisting of poly(methyl methacrylate), polyimide, and polyvinylchloride. In one embodiment, the coating is an oxide, sulfide, nitride, or ionic halide.

In one embodiment the PV device further includes top coating disposed adjacent the top major surface. Referring to FIGS. 2A and 3A, the top coating is disposed on the top surface of the HP. In one embodiment they are abutting. In another embodiment they are adjacent. The top coating provides physical protection, spectral protection, or both to the PV device. In one embodiment, the top coating is transparent (i.e., greater than 80% transmission) from 350 nm to 1300 nm. In one embodiment, the coating is a polymer selected from the group consisting of poly(methyl methacrylate), polyimide, and polyvinylchloride. In one embodiment, the coating is an oxide, sulfide, nitride, or ionic halide.

Nanofiber Electrodes

Distinct from the interdigitated thin-film electrodes disclosed above, other embodiments incorporate nanofibers embedded in the HP as electrodes. These nanofibers electrodes are still closely spaced and back-contact, so as to rely on the same design principles that enable the interdigitated electrodes. However, nanofibers electrodes provide certain manufacturing advantages because they can be relatively easily fabricated (e.g., using electrospinning), which eliminates the need for one or more photolithography steps (compared to thin-film electrodes). In one embodiment, the electron-collecting electrode comprises a mat of electron-collecting metal nanofibers. In a further embodiment, the electron-collecting metal nanofibers are coated with the electron-selective layer.

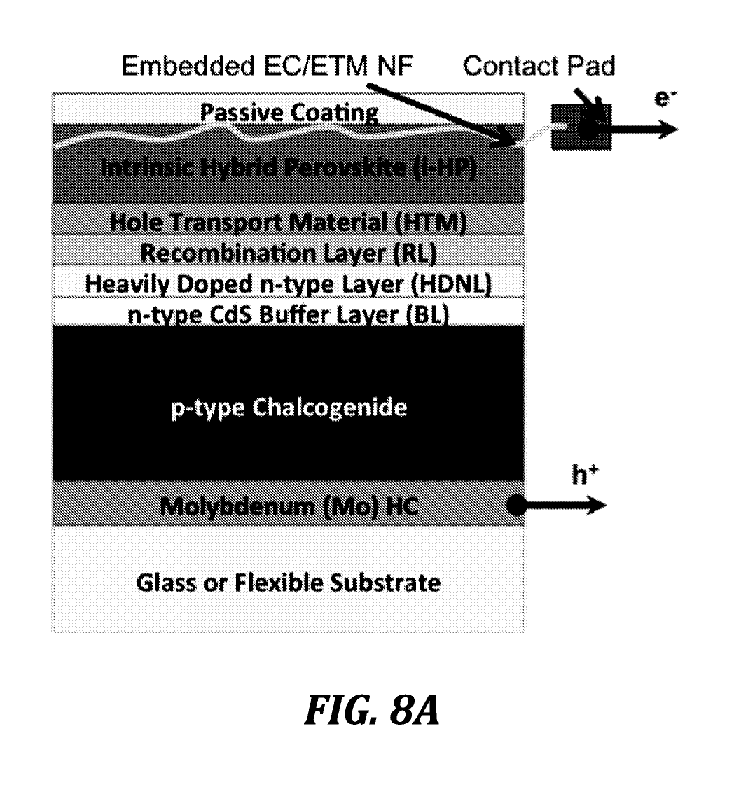

Eelectrospinning is a well-established technique capable of producing nanofibers. Several companies, such as Inovenso and Elmarco, produce industrial-scale electrospinning equipment, capable of producing over one-million square meters of material annually. In addition to polymer fibers, electrospinning of metal nanofibers (NFs) has also been reported. To form an EC electrode, metal salt is mixed with a viscosity modifier and electrospun into a nanofiber mat (e.g., FIG. 7A). The NF mat is then calcined to remove the viscosity modifier and to convert the metal salt into the metal oxide. Finally, the metal oxide fibers are reduced to the elemental metal. The mat may then be transferred to the device. Our approach adds a step to coat the metal NFs with an ETM/HBL prior to substrate transfer. The ETM can be coated at low temperature using ZnO or amorphous TiOx to prevent oxidation of the NFs. Preparing the electron contact (EC) this way has several important advantages. First, the EC fabrication is separate from the device fabrication, allowing us to relax the processing constraints. Second, it eliminates the risk of shorting that would arise if both contacts were made lithographically (no alignment concerns). Finally, all of the steps involved in making the coated NFs are readily scalable.

The nanofibers are fabricated using the same general material considerations disclosed above with regard to thin-film electrodes. Conductor-only nanofibers can be generated, or ETM or HTM layers can be grown or coated on the conductive cores of the nanofibers.

Therefore, in one embodiment, the hole-collecting electrode comprises a mat of hole-collecting metal nanofibers. In a further embodiment, the hole-collecting metal nanofibers are coated with the hole-selective layer.

In one embodiment, one or more of the electron-collecting electrode and the hole-collection electrode is a mat of metal nanofibers.

In one embodiment, both the electron-collecting electrode and the hole-collecting electrode are each a mat of metal nanofibers.

FIG. 7A is a micrograph of nanofibers comprising an electron-collector electrode core with an electron-transport material shell.

FIG. 7B is a cross-sectional diagram of nanofibers such as those in FIG. 7A.

FIG. 7C is a schematic diagram of an embodiment of EC/ETM nanofibers forming a photovoltaic device layer in accordance with the disclosed embodiments.

HP Tandem Photovoltaic Devices

In another aspect, a tandem photovoltaic device is provided. In one embodiment, the tandem PV device includes:

(1) a first photovoltaic device portion, comprising
(i) an organic-inorganic hybrid perovskite (HP) layer comprising a top major surface and a bottom major surface;
(ii) an electron-collecting electrode disposed adjacent to the bottom major surface;
(iii) an electron-selective layer forming an interface between the electron-collecting electrode and the HP; and
(iv) a hole-selective layer in contact with the bottom major surface of the HP;

(2) a second photovoltaic device portion, comprising
(i) a photovoltaic layer, having a lower energy bandgap than the HP, and having a top major surface and a bottom major surface;
(ii) a transparent conductive layer disposed adjacent to the top major surface; and
(iii) a hole-collecting electrode disposed adjacent to the top major surface; and

(3) a recombination layer forming an interface between the hole-selective layer of the first photovoltaic device portion and the transparent conductive layer of the second photovoltaic device portion; wherein the recombination layer allows holes from the first photovoltaic device portion to combine with electrons from the second photovoltaic device portion.

Tandem PV devices include at least two photovoltaic materials incorporated into two partial PV cells that are joined together at an electronic interface so as to allow operation of the device by contacting only two electrodes: one on the top partial PV cell and one on the bottom PV cell. FIG. 4 illustrates a representative tandem device in accordance with the disclosed embodiments.

The idea to combine a hybrid perovskite top cell with a low bandgap CIGSe or silicon bottom cell has been previously reported. However, these ideas all require the cell architecture to be inverted—to deposit the HP on the HTM and then deposit the compact TiO₂ and TCO on the HP. This presents issues since the HTM and HP would be damaged by the high temperature processing of the compact TiO₂ and the sputtering of a TCO. Further, doped spiro-OMeTAD (in its oxidized form, which is a preferred material) absorbs in the NIR region, preventing these photons from reaching the bottom cell. Since the top and bottom cells must be current matched, the loss is two-fold since it reduces the current one can extract from the top cell as well.

The disclosed tandem PV devices avoid both of these issues. They employ closely spaced back contact scheme with an HP top cell and traditional PV bottom cell (e.g., CIGSe or CZTSe). In addition to avoiding exposing the HP to high temperature processing steps, the unique design: (1) takes advantage of the long diffusion lengths and passive interfaces in the HP to move the top electron contact to the back side of the top cell, avoiding shadowing losses; (2) avoids current losses in the top cell (at λ<400 nm) that are usually suffered in single junction HP cells due to absorption in the top surface transparent conducting oxide; (3) relaxes the constraint on band alignment imposed by the TCO since it can now be set by the work function of the metal electron contact (EC); (4) avoids current losses in the bottom cell (for 400<λ<550 nm) that are usually suffered due to absorption in the bottom cell buffer layer (these photons are now captured by the top cell); and (4) relaxes NIR transmission constraints on the HTM, which otherwise would need to be transparent out to about 1300 nm.

Generally, the tandem PV devices disclosed herein combine an HP top cell such as those disclosed herein. The top cell is combined with a bottom cell of a type known to those of skill in the art. Joining the two portions of the devices is a recombination layer (RL) that facilitates recombination of holes and electrons flowing through the portions of the devices. By allowing recombination, the RL layer allows electrons and holes to flow from the HC and EC in order to provide power from the device, as illustrated in FIG. 4.

Any materials and device configurations disclosed here and known to those of skill in the art can be used in tandem PV devices, as long as the disclosed design considerations are satisfied.

The disclosed nanofibers electrode embodiments discussed previously are incorporated into tandem devices in certain embodiments. In this regard, FIG. 8A illustrates an exemplary two-terminal tandem PV device incorporating a top-contact nanofiber-based electron-collector electrode embedded in an HP absorber layer.

Connecting the Top and Bottom Cells

The connection between top and bottom cells is a critical aspect of a tandem solar cell. There are three necessary properties that constrain material selection for the junction between two cells: (1) high transparency to photons that can be absorbed by the bottom cell, (2) high conductivity under operating conditions and (3) availability of high density of states for barrier-free recombination of electrons from the bottom cell and holes from the top cell. The last criteria is the most limiting, as it determines the work function of the material based on the location of the conduction band of the n+ material at the top of the bottom cell and the location of the HOMO of the HTM at the bottom of the top cell. Several parallel approaches are contemplated here.

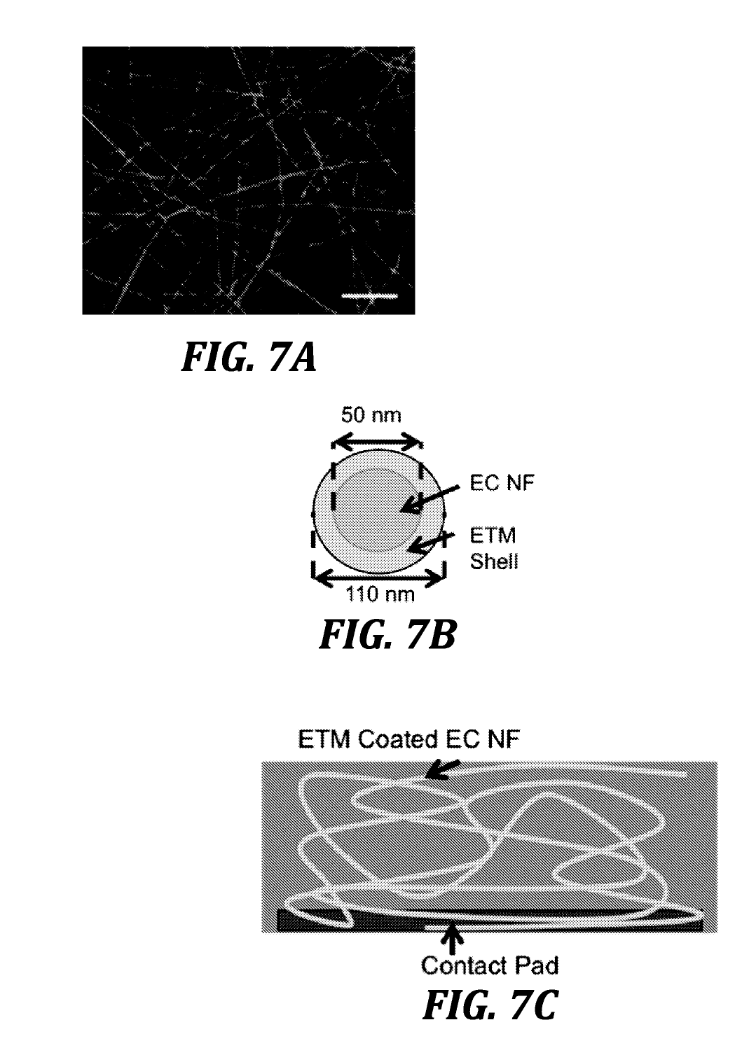

The most conventional approach is to construct an intercell tunnel junction using p⁺⁺/n⁺⁺ layers. This strategy requires two semiconductors with band gaps above 1.75 eV. If ITO is to be used for the n++ material, the ionization potential of the p⁺⁺ material must be less than 5.1 eV in order to prevent a hole barrier from forming between the spiro-OMeTAD and the tunnel junction (see FIG. 6). Transparent p-type materials that meet this constraint include CuAlO₂, SrCu₂O₂, and BaCuSF. Although the CuAlO₂ and SrCu₂O₂ TCOs are more transmissive, the BaCuSF material has higher conductivity and greater dopability.

Another strategy is to develop a highly doped “recombination layer” that may even incorporate metals, relying on the thinness of the layer or sparseness of the coverage to give transparency. This opens the possibility of establishing ohmic contact to both cells by using a material with a work function between 4.5 and 5.1 eV, provided that Schottky barriers are screened on both sides by doping in the ITO and spiro-OMeTAD. Representative materials include ultrathin films, nanowires, and nanoparticle composites of silver, gold, molybdenum, or copper. In addition, graphene (work function =4.5 eV) and PEDOT:PSS composites can be incorporated.

In one embodiment the recombination layer is selected from the group consisting of a conducting oxide, a conducting sulfide, a conducting polymer, and a conducting small organic molecule. In one embodiment, the recombination layer is a conducting oxide selected from the group consisting of TiO₂, ZnO, Al:ZnO, Ga:ZnO, In₂O₃, SnO₂, F:SnO₂, and F:In₂O₃. In one embodiment, the recombination layer is a conducting sulfide selected from the group consisting of CuS₂, SnS, and FeS. In one embodiment, the recombination layer is a conducting polymer selected from the group consisting of P3HT, graphene oxide-doped P3HT, polytriarylamine, and poly(styrensulfonate) grafted on polyaniline. In one embodiment, the recombination layer is a conducting small organic molecule selected from the group consisting of Spiro-MeTAD, triphenylamine, 1,3-Bis(N-carbazolyl)benzene, and N,N′-bis(tolyl)-N,N′ diphenyl-1, 1,'-biphenyl-4,4′-diamine.

A third strategy is to eliminate the spiro-OMeTAD layer, and replace it with a p-doped inorganic perovskite. CsPbI₃ is reported to have a band gap of 1.67 eV, and this may have the ability to increase further with incorporation of bromide. Sn⁺⁴ has been shown to act as a p-type dopant in HP's. Cs(Pb₁₋ₓSnₓ)(I_{1-y}Br_{y})₃ compounds of various x and y coordinates can be used to form a p⁺ layer that accepts electrons from ITO and holes directly from the HP. The Fermi level of the p+ perovskite must match the valence band edge of the HP, or either a barrier will form or Voc will be lost.

Exemplary Device Modeling

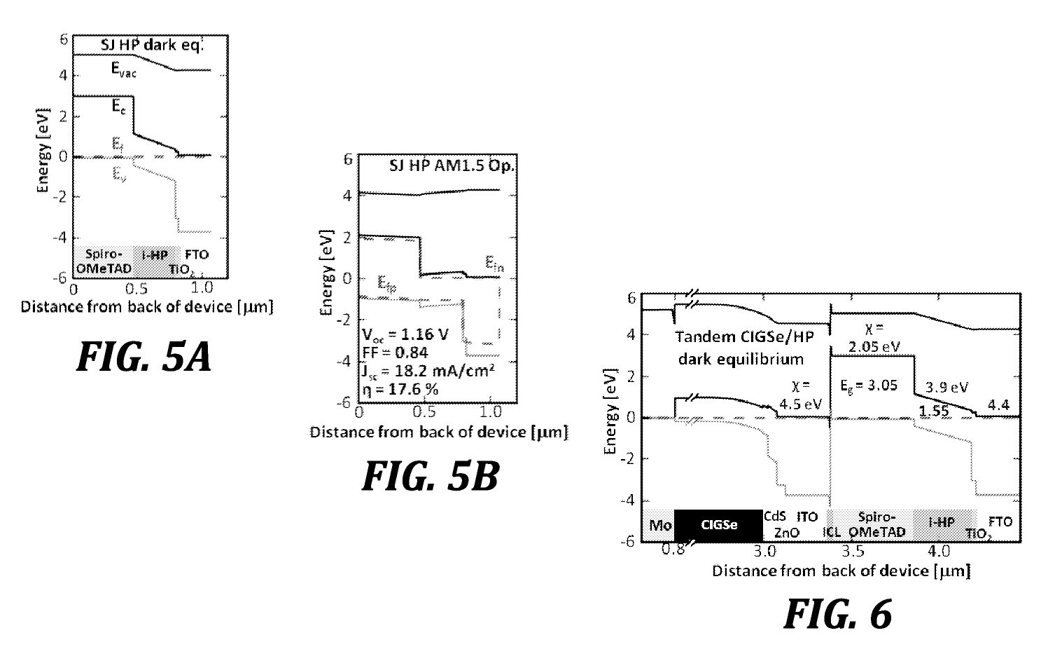

In order to both identify the design limitations of current HP single junction solar cells and to develop new tandem architectures, we developed full device simulations of single junction, tandem, and tandem-IBC architectures using Sentaurus Device, a flexible and powerful device simulation package capable of modeling 2D photovoltaic structures. As a preliminary result, we have created a single junction model of a planar hybrid perovskite device (FIGS. 5A and 5B). The HP has been modeled as an inorganic semiconductor due to the low dissociation energy Wannier-Mott type excitons with band alignment preserved according to literature reports. Our simulations reveal that much of the voltage and current losses in existing HP devices are due to poor band alignment on both sides of the HP absorber. Further, these simulations reveal that larger bandgap HP films have increasingly poor band alignment at the front of the device (poor alignment of the conduction band minimum of the HP with the Fermi level of the TCO), which will result in lower photocurrent collection efficiency. This is circumvented by the BC design because the range of work functions available for metals is much broader than that of TCOs.

We have also built preliminary 2D simulations of interdigitated back contact (IBC) single junction devices to assess the material quality required for an IBC design to exceed a conventional top contact and to help design the contact widths and spacings. Preliminary results show that with lifetimes >100 ns, diffusion lengths of ˜1 um, and passive surfaces (as already demonstrated with PMMA), the IBC design can outperform a top contact design. Further, by incorporating an ideal tunnel junction (no significant absorption or resistance) and resolving band alignment problems with the HP, the model suggests that the tandem-IBC architecture will enable the possibility of a 30% PCE tandem under AM1.5GT illumination. A band diagram of a 1D HP/CIGSe tandem is shown in FIG. 6.

Both the balance calculations and the full device models (FIG. 6) allow us to identify the key challenges that need to be solved in order to fabricate a 30% PCE tandem device under AM1.5 illumination. These are: (1) development of high-bandgap HPs that can sustain high QFLS, (2) improve band alignment by engineering new HTMs and ETMs or interfaces, (3) develop low resistance interconnection layers that allow electrons from the bottom cell to recombine with holes from the top cell without losing significant voltage, and (4) develop novel top cell designs that reduce current losses.

Top Contact PV Devices Incorporating Nanofiber Electrodes

In another aspect, a photovoltaic (PV) device is provided that includes:

an organic-inorganic hybrid perovskite (HP) layer comprising a top major surface and a bottom major surface; and

an electron-collecting electrode disposed adjacent to the bottom major surface; and

a nanofibers hole-collecting electrode disposed adjacent to the top major surface.

Embodiments of this aspect are distinct from those previously disclosed in that they do not include closely spaced EC and HC electrodes. Instead, the traditional top- and bottom-contact device configuration is used (either in a single or tandem PV architecture); however, the nanofibers electrode configuration previously discussed is used as at least the top electrode. Given the small illumination area shadowed by a nanofibers electrode, the PV devices still operate as though the top electrode is transparent.

FIG. 8A illustrates a representative device according to the present embodiments. Specifically, a nanofibers EC coated with an ETM is used as the top contact electrode in a tandem PV device.

While illustrative embodiments have been illustrated and described, it will be appreciated that various changes can be made therein without departing from the spirit and scope of the invention.

1. A photovoltaic device, comprising:
an organic-inorganic hybrid perovskite (HP) layer comprising a top major surface and a bottom major surface;
a hole-collecting electrode and an electron-collecting electrode, both disposed adjacent to the bottom major surface;
a hole-selective layer forming an interface between the hole-collecting electrode and the HP; and
an electron-selective layer forming an interface between the electron-collecting electrode and the HP.

2. The photovoltaic device of claim 1, wherein the hole-collecting electrode and the electron-collecting electrode are interdigitated.

3. The photovoltaic device of claim 2, wherein the hole-collecting electrode and the electron-collecting electrode are interdigitated in a comb-like configuration.

4. The photovoltaic device of claim 1, wherein the hole-collecting electrode comprises a mat of hole-collecting metal nanofibers.

5. The photovoltaic device of claim 4, wherein the hole-collecting metal nanofibers are coated with the hole-selective layer.

6. The photovoltaic device of claim 1, wherein the electron-collecting electrode comprises a mat of electron-collecting metal nanofibers.

7. The photovoltaic device of claim 6, wherein the electron-collecting metal nanofibers are coated with the electron-selective layer.

8. The photovoltaic device of claim 1, wherein one or more of the electron-collecting electrode and the hole-collection electrode is a mat of metal nanofibers.

9. The photovoltaic device of claim 1, wherein both the electron-collecting electrode and the hole-collecting electrode are each a mat of metal nanofibers.

10. The photovoltaic device of claim 1, wherein the OHMP has the pervoskite structure A¹⁺B²⁺X¹⁻₃, wherein A is a monovalent organic cation; B is a divalent metal cation; and X is Cl⁻, Br⁻, or I⁻.

11. The photovoltaic device of claim 1, wherein the electron-collecting electrode is a material selected from the group consisting of a metal, a metal alloy, a metal oxide, a doped metal oxide, an organic electron-conducting polymer, an organic electron-conducting small molecule, and combinations thereof.

12. The photovoltaic device of claim 1, wherein the hole-collecting electrode is a material selected from the group consisting of a metal, a metal alloy, a metal oxide, a doped metal oxide, an organic hole-conducting polymer, an organic hole-conducting small molecule, and combinations thereof.

13. The photovoltaic device of claim 1, wherein the electron-selective layer is a material selected from the group consisting of organic electron-conductive materials including C60 and C70 based PCBM and similar molecules; organic surfactants, a metal, a metal oxide, and combinations thereof.

14. The photovoltaic device of claim 1, wherein the hole-selective layer is a material selected from the group consisting of small molecule organic hole-selective materials, polymer organic hole-selective materials, and combinations thereof.

15. The photovoltaic device of claim 1, wherein the hole-collecting electrode has a width or diameter of 10 nanometers to 50 microns.

16. The photovoltaic device of claim 1, wherein the electron-collecting electrode has a width or diameter of 10 nanometers to 50 microns.

17. The photovoltaic device of claim 1, wherein the hole-collecting electrode and the electron-collecting electrode combine to cover 15% or less of the bottom major surface.

18. The photovoltaic device of claim 1, further comprising a substrate disposed adjacent the bottom major surface.

19. The photovoltaic device of claim 1, further comprising a top coating disposed adjacent the top major surface.

20. A tandem photovoltaic device, comprising:
(1) a first photovoltaic device portion, comprising
(i) an organic-inorganic hybrid perovskite (HP) layer comprising a top major surface and a bottom major surface;
(ii) an electron-collecting electrode disposed adjacent to the bottom major surface;
(iii) an electron-selective layer forming an interface between the electron-collecting electrode and the HP; and
(iv) a hole-selective layer in contact with the bottom major surface of the HP;
(2) a second photovoltaic device portion, comprising
(i) a photovoltaic layer, having a lower energy bandgap than the HP, and having a top major surface and a bottom major surface;
(ii) a transparent conductive layer disposed adjacent to the top major surface; and
(iii) a hole-collecting electrode disposed adjacent to the top major surface; and
(3) a recombination layer forming an interface between the hole-selective layer of the first photovoltaic device portion and the transparent conductive layer of the second photovoltaic device portion; wherein the recombination layer allows holes from the first photovoltaic device portion to combine with electrons from the second photovoltaic device portion.
